(19) United States
(12) Patent Application Publication
(10) Pub. No.: US 2005/0016579 A1
(43) Pub. Date: Jan. 27, 2005

(54) Solar power devices for providing power to handheld devices

(76) Inventor: Ami Elazari, Tel Aviv (IL)

Correspondence Address: Martin Moynihan;Anthony Castorina, Suite 2001, 2001 Jefferson Davis Highway, Arlington, VA, 22202, US

(21) Appl. No.: 10/502,655

(22) PCT Filed: Feb. 4, 2003
(86) PCT No.: PCT/IL03/00089

(30) Foreign Application Priority Data
Feb. 4, 2002 (US) 60353210

(51) Int. Cl. H01L 25/00

(52) U.S. Cl. 136/244

(57) ABSTRACT

An apparatus for converting solar energy to DC electrical energy, from both indoor light (artificial light) and outdoor light (sun or natural light). The present invention is suitable for providing power to a variety of handheld devices, such as PDA devices, portable computers, cellular telephones, and so forth, as well as for charging any batteries associated with such handheld devices.

### FIELD OF THE INVENTION

The present invention is related to solar power devices which are capable of performing the conversion of solar energy to electrical energy (photovoltaic principle), and in particular which are useful for providing power to handheld devices, whether indoors (inside of a building or other enclosure) or outdoors (outside of a building or other enclosure).

### BACKGROUND OF THE INVENTION

The conversion of solar energy to electrical energy through the use of systems such as photovoltaic cells, arrays, passive absorbers of solar energy, solar furnaces etc., is well established in the art. Systems have also been proposed to converting solar energy to electric energy; however, these systems employ apparatus which is complicated to fabricate, such as sealed outdoor laminated 36 solar cell enclosures.

For example, U.S. Pat. No. 4,080,221 describes a system for converting solar energy to electric energy, which employs a substantially sealed, weather tight enclosure for the solar collectors. U.S. Pat. No. 4,493,940 describes a solar collector on which photo voltaic cells are mounted with the assembly being surrounded by an enclosure that is sealed by a metal sealing collar, and U.S. Pat. No. 4,373,308 describes a flat plate solar collector in a spaced relationship to an array of photovoltaic cells.

Other systems for converting solar energy to electric and DC energy employ complex methods of transferring solar energy.

None of the above-referenced methods or devices are suitable for the conversion of solar energy to electrical energy for powering handheld devices, as these handheld devices require a sufficiently high level of power for both indoor and outdoor use.

### SUMMARY OF THE INVENTION

The background art does not teach or suggest a reliable and inexpensive system for converting solar energy to electrical energy in order to provide power to handheld devices. The background art also does not teach or suggest such a system for providing power to charge batteries for PDA devices (such as Palm Vx or Ipaq PDA, for example). The background art also does not teach or suggest such a system for providing power to charge batteries for portable (laptop and/or notebook) computers or for cellular telephones. The background art also does not teach or suggest such a system for providing power from the conversion of both indoor light (artificial light) and outdoor light (sun).

The present invention overcomes these deficiencies of the background art by providing an apparatus for converting solar (light) energy to DC (direct current) electrical energy, from both indoor light (artificial light) and outdoor light (natural light; sun). It should be noted that as used herein, the term “solar energy” refers to energy from any type of light, whether natural light, such as sunlight, or artificial light. The term “solar cell” refers to any type of photovoltaic cell or photovoltaic energy converting device. The present invention is suitable for providing power to a variety of handheld devices, such as PDA devices, portable computers, cellular telephones, and so forth, as well as for charging any batteries associated with such handheld devices.

According to a preferred embodiment of the present invention, there is provided a solar cell panel, comprising a plurality of solar cells. The panel is constructed so as to be capable of providing power from either natural or artificial light. The panel preferably features a substrate onto which the solar cells are mounted. The interconnecting material between the cells, also known as “busbars”, is also preferably mounted onto the substrate. It should be noted that the term “mounted” as used herein preferably indicates any type of connection to the substrate, including but not limited to, being glued to the substrate, being embedded in the substrate, or being an integral part thereof.

The panel preferably is constructed to reduce reflection of light, thereby increasing the amount of light being absorbed and the concomitant amount of energy being produced. Optionally and more preferably, at least a portion of the panel is coated with an anti-reflective coating.

Alternatively and more preferably, the panel is constructed from components which reduce light reflectance and/or scattering. For example, optionally and more preferably, the panel features a substrate that is constructed from a black material, such as black fiberglass for example, although alternatively any suitable material may be used. The cells are optionally and more preferably at least covered with oxidized chrome, which is known for absorbing most of the spectrum of light. Oxidized chrome, also known as “black chrome”, is known in the art for being used for the construction of solar cells. The solar cell is made from black chrome, as part of the manufacturing process, as an anti-reflective coating. Black chrome has the properties of having both low reflectance and also low emissivity, such that once light energy has been absorbed, it tends to remain trapped in the material rather than being emitted from the material. Of course, other absorbent and/or anti-reflective and/or anti-scattering material(s) may optionally be used.

The interconnecting material between the cells, also known as “busbars”, preferably features a material which is also absorbent and/or anti-reflective and/or anti-scattering. The interconnecting material also comprises an electrically conductive material. Optionally and preferably, these two characteristics are present in a single material and/or amalgamate and/or composition, such as carbon for example. Carbon (graphite) anodes or cathodes are optionally used for the manufacture of conventional non-solar cell batteries, as this material is electrically conductive. This carbon material also has the desirable property of being black, and hence absorbent and/or anti-reflective and/or anti-scattering. Graphite may therefore also be used for constructing the interconnecting material, or busbars, for the solar panel according to the present invention. This material was originally developed for the aerospace industry, and is commercially available (AD+D Ltd., Israel). Alternatively, the electrically conducive portion of the interconnecting material may optionally be coated with a coating material that is absorbent and/or anti-reflective and/or anti-scattering.

This optional but preferred embodiment of the present invention is one of many features which distinguish the present invention from the background art, as busbars are currently typically constructed from a highly reflective material such as silver or compositions which feature mixtures of metals.

According to the present invention, the combination of these different types of optional but preferred materials comprises an example of “black on black” solar panel technology according to the present invention.

According to optional but preferred embodiments of the present invention, the apparatus optionally and preferably includes a holder of some type, such as a PDA case, a portable computer bag, a sleeve for a cellular telephone, or any other holder for the device to be powered, and a solar panel according to the present invention for providing power to the device. Alternatively, as described below, the holder may optionally be constructed to hold only the solar panel(s), or alternatively and preferably, the holder features a plurality of components for holding the panel(s) and the device to be powered separately.

There is also provided in accordance with the present invention, a system for converting solar (light) energy to electrical energy including a substantially unsealed unattached enclosure surrounding an array of photovoltaic cells, and a bypass and/or blocking diode disposed on the same plane as the array of photovoltaic cells.

According to another embodiment of the present invention, there is provided an electrical system that provides power to electrical appliances such as PDA devices, portable computers and cellular telephones, in which a portion of the power is derived from the photovoltaic cells.

According to a preferred embodiment of the invention, the apparatus for converting solar energy to energy additionally includes battery bank electrically connected to the arrays of photovoltaic cells, for receiving DC electrical energy produced by the photovoltaic cells; and a DC converter for converting AC electrical power provided by the battery bank to DC electrical power. Optionally and more preferably, this apparatus includes an alternative power multiple plug source, in order for the apparatus to optionally receive electrical energy from another source when permitted or required by the battery voltage level. Also optionally and more preferably, the apparatus includes a battery charger which is electrically connected to the battery bank and the alternative power source, for charging the battery of the handheld device from the alternative power source.

A control panel may also optionally and preferably be provided, for electrically connecting and disconnecting components of the electrical system. According to a preferred embodiment of the invention the control panel includes voltage regulators.

According to yet another preferred embodiment of the invention the apparatus for converting solar energy to electrical energy additionally includes apparatus to transfer electric power from the photovoltaic cells to any electric power device when the battery bank is fully charged, for example by using the special multiple plug device.

According to a preferred embodiment of the invention, the apparatus for converting solar energy to electrical energy further preferably includes a unique solar cell arrangement that enables the apparatus to work both indoor, converting artificial light to DC (direct current), and outdoor, converting sun light to DC.

### BRIEF DESCRIPTION OF THE DRAWINGS

The present invention will be understood and appreciated more fully from the following detailed description, taken in conjunction with the drawings in which:

FIG. 1 is a schematic block diagram of an exemplary solar cell (photovoltaic cell) circuit according to the present invention;

FIG. 2 is a schematic block diagram of an exemplary panel according to the present invention;

FIG. 3 is a schematic block diagram of an exemplary system according to the present invention;

FIG. 4 shows a photograph of an exemplary panel according to the present invention;

FIGS. 5A and 5B show photographs of two aspects of an exemplary holder according to the present invention; and

FIG. 6 shows a photograph of another exemplary holder according to the present invention.

### DETAILED DESCRIPTION OF PREFERRED EMBODIMENTS

The present invention is of an apparatus, system and method for converting solar (light) energy to DC (direct current) electrical energy, from both indoor light (artificial light) and outdoor light (sun). It should be noted that as used herein, the term “solar energy” refers to energy from any type of light, whether natural light, such as sunlight, or artificial light. The term “solar cell” refers to any type of photovoltaic cell or photovoltaic energy converting device. The present invention is suitable for providing power to a variety of handheld devices, such as PDA devices, portable computers, cellular telephones, and so forth, as well as for charging any batteries associated with such handheld devices.

According to a preferred embodiment of the present invention, the apparatus features a solar cell panel, comprising a plurality of solar cells. The panel is constructed so as to be capable of providing power from either natural or artificial light. The panel preferably features a substrate onto which the solar cells are mounted. The interconnecting material between the cells, also known as “busbars”, is also preferably mounted onto the substrate. It should be noted that the term “mounted” as used herein preferably indicates any type of connection to the substrate, including but not limited to, being glued to the substrate, being embedded in the substrate, or being an integral part thereof.

The panel preferably is constructed to reduce reflection of light, thereby increasing the amount of light being absorbed and the concomitant amount of energy being produced. Optionally and more preferably, at least a portion of the panel is coated with an anti-reflective coating.

Alternatively and more preferably, the panel is constructed from components which reduce light reflectance and/or scattering. For example, optionally and more preferably, the panel features a substrate that is constructed from a black material, such as black fiberglass for example, although alternatively any suitable material may be used. The cells are optionally and more preferably at least covered with oxidized chrome, which is known for absorbing most of the spectrum of light. Oxidized chrome, also known as “black chrome”, is known in the art for being used for the construction of solar cells. Black chrome has the properties of having both low reflectance and also low emissivity, such that once light energy has been absorbed, it tends to remain trapped in the material rather than being emitted from the material. Of course, other absorbent and/or anti-reflective and/or anti-scattering material(s) may optionally be used.

The interconnecting material between the cells, also known as “busbars”, preferably features a material which is also absorbent and/or anti-reflective and/or anti-scattering. The interconnecting material also comprises an electrically conductive material. Optionally and preferably, these two characteristics are present in a single material and/or amalgamate and/or composition, such as carbon for example. Carbon (graphite) anodes or cathodes are optionally used for the manufacture of conventional non-solar cell batteries, as this material is electrically conductive. This carbon material also has the desirable property of being black, and hence absorbent and/or anti-reflective and/or anti-scattering. Graphite may therefore also be used for constructing the interconnecting material, or busbars, for the solar panel according to the present invention. Alternatively, the electrically conducive portion of the interconnecting material may optionally be coated with a coating material that is absorbent and/or anti-reflective and/or anti-scattering.

This optional but preferred embodiment of the present invention is one of many features which distinguish the present invention from the background art, as busbars are currently typically constructed from a highly reflective material such as silver or compositions which feature mixtures of metals.

According to the present invention, the combination of these different types of optional but preferred materials comprises an example of “black on black” solar panel technology according to the present invention.

The array of photovoltaic cells optionally and preferably includes 18-36 single-crystal silicon outdoor EFG solar cells, which may optionally each have the dimensions of 5 cm×1.25 cm, fabricated from Czochralski-grown ingots, as examples of a special monocrystalline high efficiency indoor/outdoor photovoltaic cell. The array also preferably includes 18-36 cells of thinfilm Sanio amron indoor PV (photovoltaic) cells, alternating between indoor and outdoor cells, optionally in strings of 18-36 cells.

Each array optionally and preferably contains 10 rows of 9-18 square cells. As described in greater detail below, the size of the cells and of the arrays (e.g. number of cells in each row and total array) is preferably determined according to the electrical power to be output. Each row is preferably capable of producing up to 10 Watts per/hour and each array is preferably capable of producing up to 20 Watts per day (2 Amps at 12 Volts).

According to optional but preferred embodiments of the present invention, the apparatus optionally and preferably includes a holder of some type, such as a PDA case, a portable computer bag, a sleeve for a cellular telephone, or any other holder for the device to be powered, and a solar panel according to the present invention for providing power to the device. Alternatively, as described below, the holder may optionally be constructed to hold only the solar panel(s), or alternatively and preferably, the holder features a plurality of components for holding the panel(s) and the device to be powered separately.

The present invention is suitable for operation with any type of electronic device, including but not limited to, a CD player, an MP3 player, a laptop or other portable computer, a cellular telephone, a digital video camera, a jukebox or a GPS device.

Different configurations and arrangements may optionally be used for the holder and the panel. For example, one or more panels may optionally be located outside of the holder, and are then preferably connected to the device within the holder, for example by being connected to the battery or batteries for the device. If the panel is located on the outside of the holder, it may optionally be protected with a transparent or translucent (e.g. partially light-transmitting) cover, such as a cover constructed from a suitable plastic material for example. Alternatively, one or more panels may optionally be located inside the holder, such that the holder may opened to permit light to reach the solar panel(s). The device may then optionally be held in a separate compartment of the holder, or alternatively may be kept outside of the holder, and only connected to the solar panel(s) through a plug of some type.

According to optional but preferred embodiments of the present invention, the plug may optionally feature two portions: a first part that is specific to the type of device and/or product being powered, for example being constructed according to the requirements of the manufacturer; and a second part that is connected to the solar panel(s), and which features a “universal connector” at the end. This universal connector would then be connectable to a portion of the first part of the connector. For example, the universal connector could optionally feature a female connector, while the first part would feature a connector that is specifically designed for the particular type of device and/or product (i.e. according to a configuration of the power socket at the device), and a male connector that is adapted to be connectable to the female connector on the universal connector.

According to a further preferred embodiment of the invention, the holder for the handheld device is formed from an insulating material.

According to a further preferred embodiment of the invention the wires or busbars, which connect the components of the electrical circulation system, are fabricated from a rust resistant material.

According to a preferred embodiment of the invention, the holder comprises a frame, a back plate, an EVA cover and Scotch adhesive material disposed between the back plate and frame of the enclosure, for connecting the back plate to the frame. EVA is a transparent material, like glass, hard glass lamination, or clear epoxy, which allows passage of light. Clear epoxy was developed for use in outer space as a tough, resistant material. EVA may optionally be hardened by heating. The cells are optionally and preferably held between two layers of EVA. Alternatively, the cells may optionally be laminated with Tefzel™ (Dupont, USA), which is heated after being added to the cells to form the laminate.

Various connectors are preferably provided in order to interconnect the electrical components of the system, optionally and more preferably through openings in the frame to permit electrical connections to the photovoltaic cells of the panel and the handheld device or other device being powered. Most preferably, these connections are provided to the battery of the handheld device or other device being powered.

The panel according to the present invention is optionally and preferably held in a portion of the holder, such that that photovoltaic (solar) cells are exposable to light. For example, the frame may optionally feature panel holders for holding the panel, preferably for holding the back of the panel and/or the corners of the panel, and/or a portion of the panel and/or a component connected to the panel that preferably does not feature photovoltaic cells, and instead is adapted for acting as a “handle” for the panel.

According to a further preferred embodiment of the invention, the frame and back plate are fabricated from a light fiberglass material.

According to another preferred embodiment of the invention the EVA cover is movably attached to the frame, and is more preferably removable from the frame.

There is also provided in accordance with the present invention, a system for converting solar (light) energy to electrical energy including a substantially unsealed unattached enclosure surrounding an array of photovoltaic cells, and a bypass diode disposed on the same plane as the array of photovoltaic cells.

According to another embodiment of the present invention, there is provided an electrical system that provides power to electrical appliances such as PDA devices, portable computers and cellular telephones, in which a portion of the power is derived from the photovoltaic cells.

According to a preferred embodiment of the invention, the apparatus for converting solar energy to energy additionally includes a battery bank electrically connected to the arrays of photovoltaic cells, for receiving DC electrical energy produced by the photovoltaic cells; and a DC converter for converting AC electrical power provided by the battery bank to DC electrical power. Optionally and more preferably, this apparatus includes an alternative power source, in order for the apparatus to optionally receive electrical energy from another source when permitted or required by the battery voltage level. Also optionally and more preferably, the apparatus includes a battery charger which is electrically connected to the battery bank and the alternative power source, for charging the battery of the handheld device from the alternative power source.

When the voltage level of the solar photovoltaic cells permits, optionally the apparatus may provide power to other appliances, for example through circuits which provide such AC and/or DC electrical power.

A control panel may also optionally and preferably be provided, for electrically connecting and disconnecting components of the electrical system. According to a preferred embodiment of the invention the control panel includes voltage regulators.

The photovoltaic array (panel according to the present invention) is preferably electrically connected to an electrical system. The electrical system preferably includes a battery bank, or plurality of batteries, connected by cables to the photovoltaic array. The battery bank is also preferably connected through the control panel to circuits which provide DC electrical power to the handheld device and/or other electrical appliances. This battery bank is also optionally and preferably connected by a multi-plug cable to a DC/AC converter. The converter converts the DC current of the battery bank to 220 V or 110 volt, 50 Hz AC current, and supplies the current to certain circuits, which provide AC electrical power to the electrical appliances. The multi-plug device is preferably capable of being connected to the electrical appliances.

The battery bank typically comprises at least one sealed battery, with a capacity of 1.00 to 2.00 AH at a 20 hour rate. A suitable commercially available battery is the LI-ION battery manufactured by SEC Ltd., Inver Bucks SL 09 AG, United Kingdom. The control panel and the converter are typically included in a single commercially available power supply unit such as the TRACE manufactured by Photocomm Inc., Scottsdale Ariz., USA.

According to yet another preferred embodiment of the invention the apparatus for converting solar energy to electrical energy additionally includes apparatus to transfer electric power from the photovoltaic cells to any electric power device when the battery bank is fully charged, for example by using the special multiple plug device.

According to a preferred embodiment of the invention, the apparatus for converting solar energy to electrical energy further preferably includes a unique solar cell arrangement that enables the apparatus to work both indoor, converting artificial light to DC (direct current), and outdoor, converting sun light to DC. As previously described, this arrangement preferably uses the “black on black” technology according to the present invention, for maximum efficiency of operation of the solar cells.

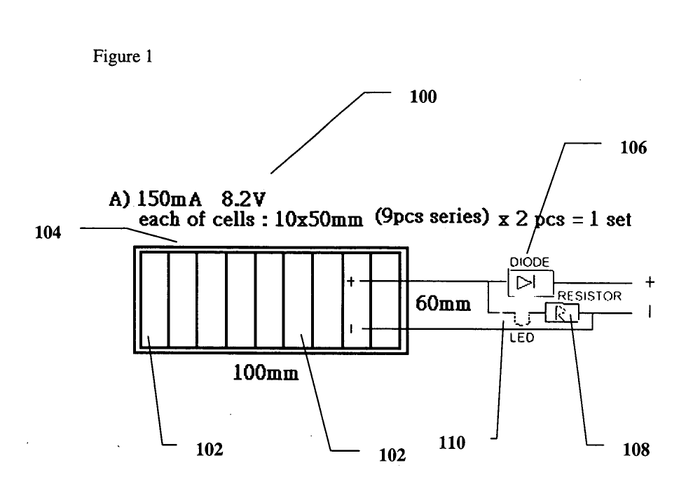

The principles and operation of the present invention may be better understood with reference to the drawings and the accompanying description. Reference is now made to FIG. 1, which shows a schematic block diagram of an exemplary solar cell (photovoltaic cell) circuit according to the present invention. As shown, a circuit 100 features a plurality of photovoltaic cells 102 (AEG AG, Germany). In the exemplary implementation of circuit 100 shown, nine photovoltaic cells 102, although it should be understood that this is for the purposes of discussion only and is without any intention of being limiting. The size of each photovoltaic cell 102, and the number included in circuit 100, are optionally and preferably determined according to the amount of power to be produced. For example, optionally and preferably each photovoltaic cell 102 may be about 10 mm by about 50 mm. Circuit 100 would then be about 100 mm in length and 60 mm in width as shown. Of course, any suitable size or number of photovoltaic cells 102 and/or circuit 100 may optionally be used. For circuit 100 as shown, this implementation would produce about 150 mA and 8.2 V of electrical energy.

Photovoltaic cells 102 preferably feature a busbar 104 as an example of interconnecting material between photovoltaic cells 102, more preferably as a grid between photovoltaic cells 102.

Circuit 100 also preferably features a blocking or bypass diode 106, for forcing the current to only flow in one direction. Blocking diode 106 is preferably connected in series to photovoltaic cells 102 as shown, for protecting photovoltaic cells 102 from a reverse power flow, and hence protects photovoltaic cells 102 from thermal destruction (which could occur if such a reverse power flow would not be blocked). Blocking diode 106 may also optionally be implemented as a bypass diode, which is connected across one or more photovoltaic cells 102 (not shown) and which therefore conducts if the one or more photovoltaic cells 102 become reverse biased. The bypass diode may also optionally be connected anti-parallel across a portion of the plurality of photovoltaic cells 102, for example to protect photovoltaic cells 102 from thermal destruction.

Circuit 100 also preferably features a resistor 108 for regulating the level of the current and voltage. Optionally and preferably, circuit 100 features a LED (light emitting diode) 110 or other light emitting device, for showing to the user that circuit 100 is capable of providing electrical energy.

Circuit 100 is also preferably connected (through resistor 108) to the device to be powered (not shown).

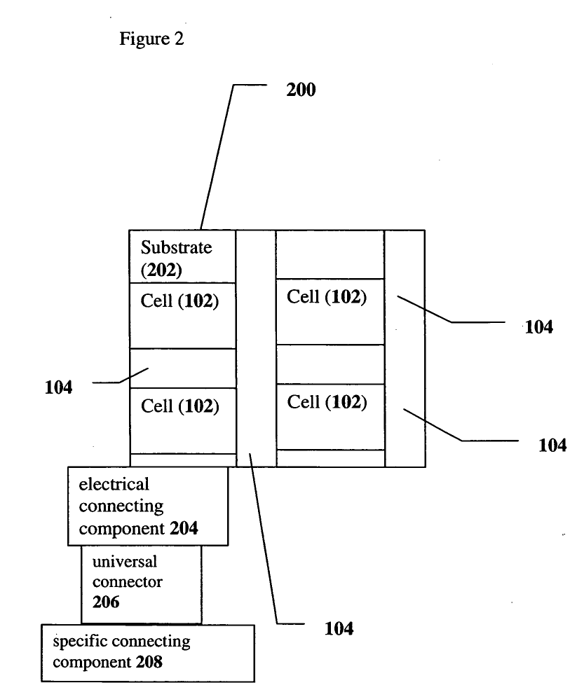

FIG. 2 is a schematic block diagram of an exemplary panel according to the present invention. It should be noted that FIG. 2 is highly schematic; of necessity, certain components are not depicted, in order to render the relationship between the remaining components more clearly. Also, the components are shown in FIG. 2 according to their logical relationship, and not necessarily according to physical location.

FIG. 2 shows a panel 200, featuring a plurality of photovoltaic cells 102, connected by an interconnecting material such as busbar 104 for example. Photovoltaic cells 102 are preferably mounted on a substrate 202, optionally with a glue or other adhesive substance. Busbar 104 is also preferably mounted on substrate 202, also optionally with a glue or other adhesive substance.

As previously described, each of photovoltaic cells. 102, busbar 104 and substrate 202 is preferably constructed of a substantially absorbent, and/or anti-reflective and/or anti-scattering material, which also preferably features low emissivity as previously described. For example, photovoltaic cells 102 are optionally and more preferably at least covered with oxidized chrome, also known as “black chrome”. Photovoltaic cells 102 may optionally be purchased with the black chrome (black anti-reflective coating) material already present. Busbar 104 also comprises an electrically conductive material. Optionally and preferably, these two characteristics are present in a single material and/or amalgamate and/or composition, such as carbon for example. Carbon (graphite) may optionally be used, as this material is electrically conductive. Alternatively, busbar 104 may optionally be coated with a coating material that is absorbent and/or anti-reflective and/or anti-scattering.

According to the present invention, the combination of these different types of optional but preferred materials comprises an example of “black on black” solar panel technology according to the present invention.

Panel 200 also preferably features an electrical connecting component 204, which optionally and more preferably features the resistor and blocking and/or bypass diode of FIG. 1 (not shown), and optionally and most preferably features the LED of FIG. 1 (not shown). Electrical connecting component 204 also preferably features a universal connector 206, which is preferably capable of connecting to a specific connecting component 208. Specific connecting component 208 preferably features one end that is capable of connecting to universal connector 206, and another end that is capable of connectably providing power to the device to be powered (not shown).

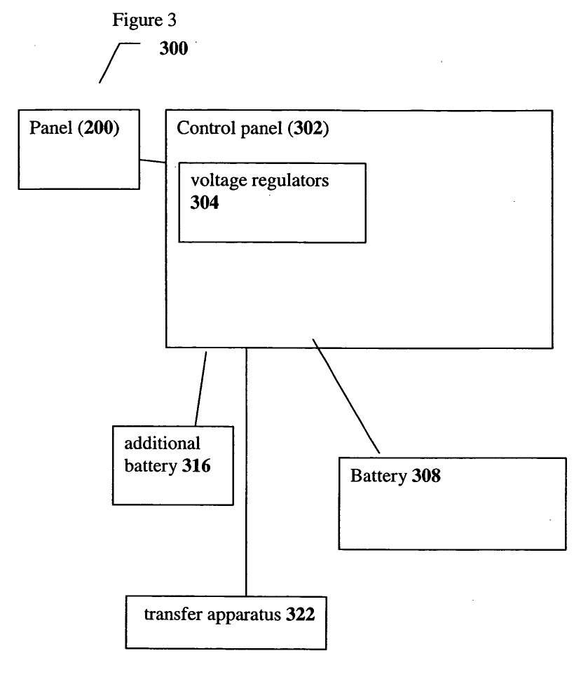

FIG. 3 is a schematic block diagram of an exemplary system according to the present invention. Again, it should be noted that FIG. 3 is highly schematic; of necessity, certain components are not depicted, in order to render the relationship between the remaining components more clearly. Also, the components are shown in FIG. 3 according to their logical relationship, and not necessarily according to physical location.

FIG. 3 shows a system 300, featuring panel 200 of FIG. 2. Panel 200 is optionally and preferably connected to a control panel 302. As shown, a plurality of panels 200 is preferably connected to control panel 302. Control panel 302 preferably electrically connects and disconnects components of system 300. According to a preferred embodiment of the invention, control panel 302 preferably includes at least one, and more preferably a plurality of voltage regulators 304 as shown. A battery 308 may optionally be connected to the device to be powered (not shown), and is typically part of the device to be powered. An AC circuit may optionally be present between battery 308 and panel 200.

Control panel 302 may also optionally and preferably feature a transfer apparatus 322 for transferring electric power from photovoltaic cells 102 to any electrically powered device (not shown) when battery 308 is fully charged, for example by using a multiple plug device (not shown). An additional battery 316 may optionally be used as a buffer battery, for example if there is not sufficient light to power the device to receive power, and/or to start charging. Battery 316 preferably is rechargeable, so as to be able act as a small reservoir of power. Such an implementation is particularly preferred when a significant amount of power is required, for example for a laptop or other device, and/or as a back-up power source, and/or in a situation in which sufficient light is not available. Preferably, battery 316 is adapted to be held within a holder for holding the device to be charged (not shown).

Battery 308 may optionally be implemented as a plurality of batteries in a battery bank for any of the above configurations.

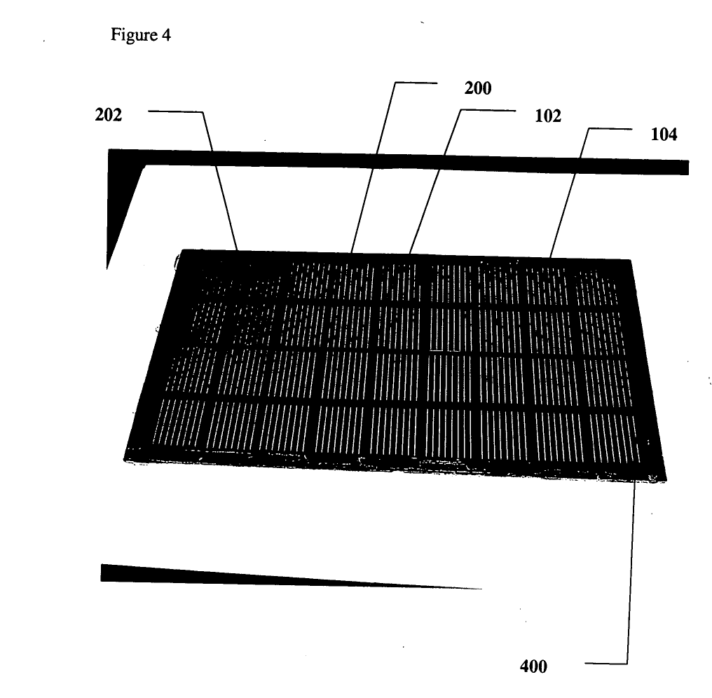

FIG. 4 shows a photograph of panel 200 according to the present invention. Photovoltaic cells 102 and busbar 104 are clearly visible, as is substrate 202. A portion of substrate 202 may optionally serve as a handle 400.

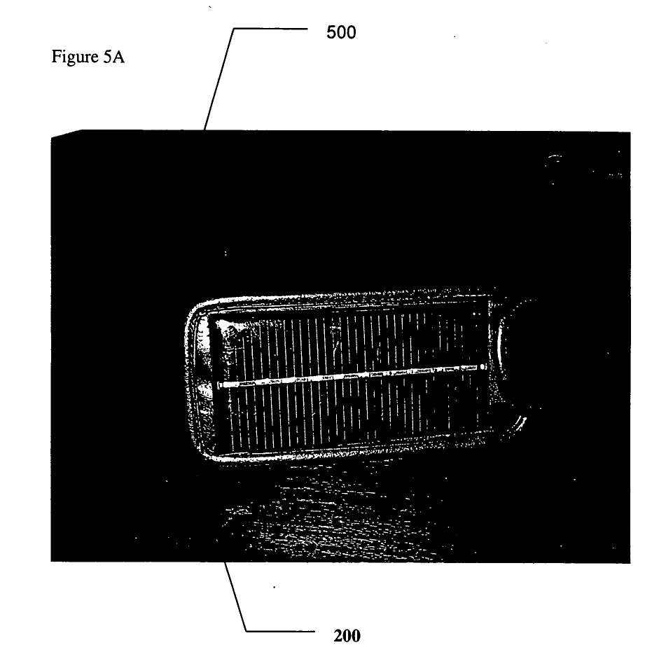

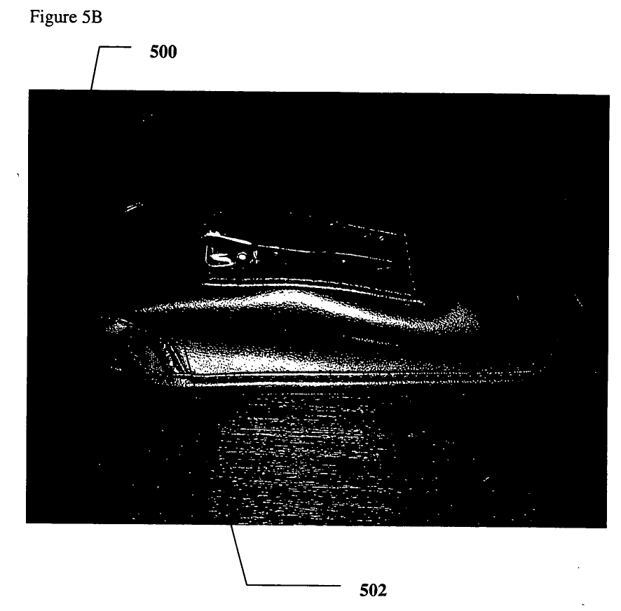

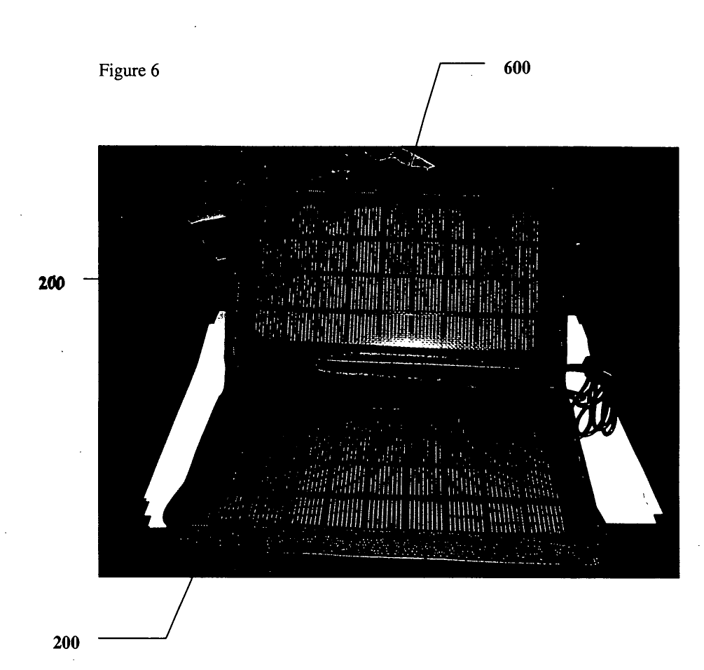

FIGS. 5 and 6 show illustrative, non-limiting examples of holders according to the present invention, for operation with an electronic device.

FIGS. 5A and 5B show a photograph of an exemplary holder 500 for holding and providing power to a cellular telephone, PDA or other such handheld and/or portable device. It should be noted that holder 500 does not need to hold the device to be charged during operation, and actually preferably does not hold the device to be charged during operation. Holder 500 features panel 200 as shown in FIG. 5A FIG. 5B shows the back (other side) of holder 500, showing an optional carrying clip 502.

FIG. 6 shows another holder 600, which contains two panels 200 inside; when holder 600 is closed, panels 200 are protected but also cannot receive light. Opening holder 600, as shown with regard to FIG. 6, enables panels 200 to receive light and to provide power.

It will be appreciated that the above descriptions are intended only to serve as examples, and that many other embodiments are possible within the spirit and the scope of the present invention.

1. A panel for providing power, comprising:
(a) a plurality of photovoltaic cells, said photovoltaic cells being capable of generating electrical power from both artificial and natural light;
(b) interconnecting material for electrically connecting said plurality of photovoltaic cells; and
(c) a substrate for mounting said photovoltaic cells and said interconnecting material, such that said photovoltaic cells and said interconnecting material are arranged in an array on said substrate;
wherein said photovoltaic cells, said interconnecting material and said substrate each feature at least reduced reflectance.

2. The panel of claim 1, wherein said photovoltaic cells comprise oxidized chrome.

3. The panel of claim 1, wherein said interconnecting material comprises a busbar.

4. The panel of claim 3, wherein said busbar comprises graphite.

5. The panel of claim 1, wherein said substrate comprises black fiberglass.

6. The panel of claim 1, further comprising an electrical circuit for connectably providing power from said plurality of photovoltaic cells.

7. The panel of claim 6, wherein said electrical circuit further comprises a resistor for regulating a flow of current from said plurality of photovoltaic cells.

8. The panel of claim 7, wherein said electrical circuit further comprises at least one of a bypass diode or a blocking diode.

9. The panel of claim 6, further comprising an LED (light emitting diode).

10. A system for providing power to an electronic device, comprising:
(a) a panel comprising:
(i) a plurality of photovoltaic cells, said photovoltaic cells being capable of generating electrical power from both artificial and natural light;
(ii) interconnecting material for electrically connecting said plurality of photovoltaic cells; and
(iii) a substrate for mounting said photovoltaic cells and said interconnecting material, such that said photovoltaic cells and said interconnecting material are arranged in an array on said substrate; and
(b) an electrical circuit for providing power to the device.

11. The system of claim 10, wherein said electrical circuit further comprises a resistor for regulating a flow of current from said plurality of photovoltaic cells.

12. The system of claim 11, wherein said electrical circuit further comprises at least one of a bypass diode or a blocking diode.

13. The system of claim 10, further comprising an LED (light emitting diode).

14. The system of claim 10, further comprising a battery for being connected to the device, wherein said panel provides power to said battery, such that said panel is electrically connected to said battery through said electrical circuit.

15. The system of claim 10, further comprising a battery bank for being connected to the device, wherein said panel provides power to said battery bank, such that said panel is electrically connected to said battery bank through said electrical circuit.

16. The system of claim 15, further comprising an additional battery.

17. The system of claim 16, wherein said additional battery provides a reservoir of power.

18. The system of claim 17, wherein said additional battery provides said power at least when sufficient light is not available.

19. The system of claim 17, wherein said additional battery provides said power at least when additional power is required.

20. The system of claim 16, wherein said additional battery is rechargeable from said panel.

21. The system of claim 10, wherein said photovoltaic cells, said interconnecting material and said substrate each feature at least reduced reflectance.

22. An apparatus for providing power to a handheld device, comprising:
(a) a holder for holding the handheld device;
(b) at least one solar cell array located in a portion of said holder, said at least one solar cell array being capable of generating electrical power from both artificial light and natural light; and
(c) at least one circuit for electrically connecting said at least one solar cell array to the handheld device, such that power is provided to the handheld device.

23. The apparatus of claim 22, wherein said solar cell array is located in an exterior panel of said holder.

24. The apparatus of claim 22, wherein said solar cell array is located in an interior panel of said holder.

25. The apparatus of claim 22, further comprising a universal connector for being connected to said electrical circuit and a specific connector for being connected to the handheld device, said universal connector featuring one end for being connected to one end of said specific connector, said specific connector featuring another end for being connectable to the handheld device, a configuration of said other end being determined according to a configuration of a power socket at the handheld device, such that power is provided to the handheld device.

26. The apparatus of claim 22, further comprising a multi-plug unit for providing power to a plurality of electrical appliances.

27. The apparatus of claim 22, further comprising an additional connector for connection to an external power source, wherein power is provided to the handheld device from said external power source if a power output by said at least one solar cell array falls below a predetermined level.

28. The apparatus of claim 22, wherein said at least one solar cell array comprises a plurality of special monocrystalline high efficiency indoor/outdoor photovoltaic cells.
